(19) United States
(12) Patent Application Publication
(10) Pub. No.: US 2013/0049188 A1
(43) Pub. Date: Feb. 28, 2013

(54) Semiconductor Device and Method of Forming TIM Within Recesses of MUF Material

(71) Applicants: DaeSik Choi, Seoul (KR); OhHan Kim, Kyonggi-do (KR); MinWook Yu, Gyeonggi-do (KR)

(72) Inventors: DaeSik Choi, Seoul (KR); OhHan Kim, Kyonggi-do (KR); MinWook Yu, Gyeonggi-do (KR)

(73) Assignee: STATS CHIPPAC, LTD., Singapore (SG)

(21) Appl. No.: 13/218,388

(22) Filed: Aug. 25, 2011

(51) Int. Cl. H01L 23/34; H01L 21/56

(52) U.S. Cl. 257/717; 438/122; 257/E23.08; 257/E21.502

(57) ABSTRACT

A semiconductor device has a semiconductor die mounted to a substrate. The semiconductor die and substrate are disposed within a mold chase with a releasing layer disposed over the semiconductor die. A MUF material is deposited around the semiconductor die, releasing layer, and substrate through an opening in the mold chase. The opening in the mold chase is located in an upper mold support of the mold chase. A recess is formed in the MUF material by removing the releasing layer. A TIM is formed in the recess of the MUF material. The TIM is substantially coplanar with the MUF material. A heat spreader is formed over the TIM material. The heat spreader can be formed within the recess of the MUF material over the TIM. A plurality of bumps is formed over a surface of the substrate opposite the semiconductor die.

### FIELD OF THE INVENTION

The present invention relates in general to semiconductor devices and, more particularly, to a semiconductor device and method of forming a thermal interface material (TIM) within recesses of mold underfill (MUF) material to reduce pump-out and enhance thermal conductivity.

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each die is typically identical and contains circuits formed by electrically connecting active and passive components. The term “semiconductor die” as used herein refers to both the singular and plural form of the word, and accordingly can refer to both a single semiconductor device and multiple semiconductor devices. Back-end manufacturing involves singulating individual die from the finished wafer and packaging the die to provide structural support and environmental isolation.

One goal of semiconductor manufacturing is to produce smaller semiconductor devices. Smaller devices typically consume less power, have higher performance, and can be produced more efficiently. In addition, smaller semiconductor devices have a smaller footprint, which is desirable for smaller end products. A smaller die size can be achieved by improvements in the front-end process resulting in die with smaller, higher density active and passive components. Back-end processes may result in semiconductor device packages with a smaller footprint by improvements in electrical interconnection and packaging materials.

Another goal of semiconductor manufacturing is to produce semiconductor devices with adequate heat dissipation. High frequency semiconductor devices generally generate more heat. Without effective heat dissipation, the generated heat can reduce performance, decrease reliability, and reduce the useful lifetime of the semiconductor device.

FIG. 1a shows a conventional semiconductor package 10 with a semiconductor die 12 having an active surface 14. Bumps 16 are formed on contact pads 18 on active surface 14. Semiconductor die 12 is mounted to substrate 20 with bumps 16 electrically connected to conductive traces 22 on the substrate. Bumps 24 are formed on conductive traces 22 opposite semiconductor die 12. An encapsulant 26 is deposited over semiconductor die 12 and substrate 20. Encapsulant 26 is substantially coplanar with back surface 28 of semiconductor die 12. A TIM 30 is formed over back surface 28 of semiconductor die 12. A heat spreader or heat sink 32 is positioned over and mounted to TIM 30 over semiconductor die 12 and encapsulant 26, as shown in FIG. 1b. The pressure of mounting heat spreader 32 to encapsulant 26 forces a spreading or pump-out of TIM 30 from back surface 28 of semiconductor die 12 over encapsulant 26. The pump-out of TIM 30 can also occur during power cycling and other conditions of thermal mechanical stress of semiconductor package 10. The pump-out of TIM 30 over encapsulant 26 reduces the thickness of the TIM over back surface 28 of semiconductor die 12 to less than its design thickness. The pump-out of TIM 30 can also create voids in the TIM over back surface 28. The thinner coverage of TIM 30 over back surface 28, as well as the potential voids, reduces the thermal conductivity and efficiency of TIM 30 and heat spreader 32. The pump-out of TIM 30 can cause overheating and reduce the mean time between failures of semiconductor package 10.

### SUMMARY OF THE INVENTION

A need exists to maintain a design thickness of the TIM for efficient thermal conductivity. Accordingly, in one embodiment, the present invention is a method of making a semiconductor device comprising the steps of providing a substrate, mounting a semiconductor die to the substrate, disposing a releasing layer over the semiconductor die, depositing a mold underfill material around the semiconductor die, releasing layer, and substrate, forming a recess in the mold underfill material by removing the releasing layer, forming a thermal interface material in the recess of the mold underfill material, and forming a heat spreader over the thermal interface material.

In another embodiment, the present invention is a method of making a semiconductor device comprising the steps of providing a substrate, mounting a semiconductor die to the substrate, depositing an encapsulant around the semiconductor die and substrate while blocking formation of the encapsulant over the semiconductor die to form a recess in the encapsulant over the semiconductor die, forming a thermal interface material in the recess of the encapsulant, and forming a heat spreader over the thermal interface material.

In another embodiment, the present invention is a method of making a semiconductor device comprising the steps of providing a substrate, mounting a semiconductor die to the substrate, depositing an encapsulant around the semiconductor die and substrate, forming a recess in the encapsulant over the semiconductor die, forming a thermal interface material in the recess of the encapsulant, and forming a heat spreader over the thermal interface material.

In another embodiment, the present invention is a semiconductor device comprising a substrate and semiconductor die mounted to the substrate. An encapsulant is deposited around the semiconductor die and substrate with a recess formed in the encapsulant over the semiconductor die. A thermal interface material is formed in the recess of the encapsulant. A heat spreader is formed over the thermal interface material.

### BRIEF DESCRIPTION OF THE DRAWINGS

FIGS. 1a-1b illustrate a conventional semiconductor package with TIM and heat spreader;

FIG. 2 illustrates a printed circuit board (PCB) with different types of packages mounted to its surface;

FIGS. 3a-3c illustrate further detail of the representative semiconductor packages mounted to the PCB;

FIGS. 4a-4c illustrate a semiconductor wafer with a plurality of semiconductor die separated by a saw street;

FIGS. 5a-5q illustrate a process of forming a TIM within recesses of a MUF material;

FIG. 6 illustrates the TIM formed within the recesses of the MUF material according to FIGS. 5a-5q;

FIGS. 7a-7l illustrate a process of forming a TIM and heat spreader within recesses of a MUF material; and

FIG. 8 illustrates the TIM and heat spreader formed within the recesses of the MUF material according to FIGS. 7a-7l.

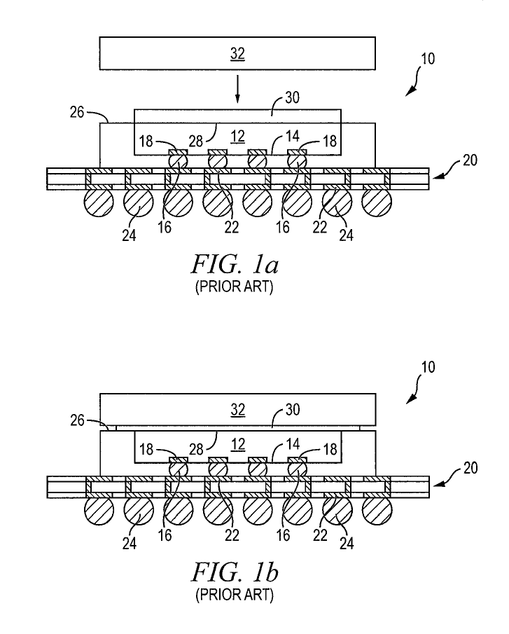

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition can involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. In one embodiment, the portion of the photoresist pattern subjected to light is removed using a solvent, exposing portions of the underlying layer to be patterned. In another embodiment, the portion of the photoresist pattern not subjected to light, the negative photoresist, is removed using a solvent, exposing portions of the underlying layer to be patterned. The remainder of the photoresist is removed, leaving behind a patterned layer. Alternatively, some types of materials are patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface is required to produce smaller and more densely packed active and passive components. Planarization can be used to remove material from the surface of the wafer and produce a uniformly flat surface. Planarization involves polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer is singulated using a laser cutting tool or saw blade. After singulation, the individual die are mounted to a package substrate that includes pins or contact pads for interconnection with other system components. Contact pads formed over the semiconductor die are then connected to contact pads within the package. The electrical connections can be made with solder bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

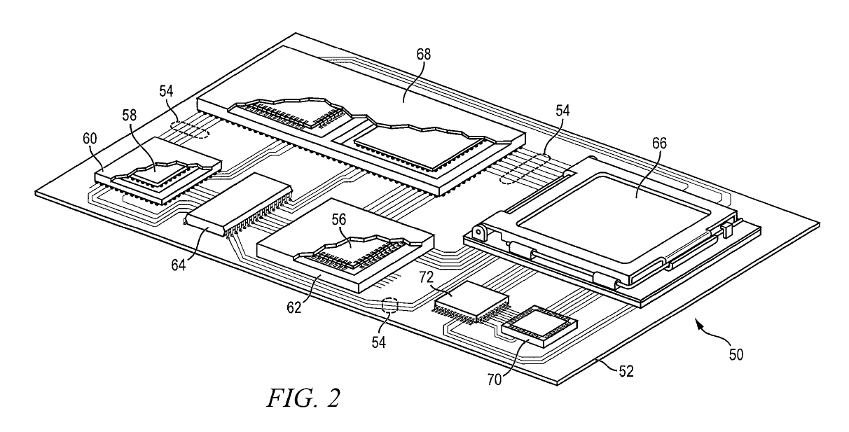

FIG. 2 illustrates electronic device 50 having a chip carrier substrate or printed circuit board (PCB) 52 with a plurality of semiconductor packages mounted on its surface. Electronic device 50 can have one type of semiconductor package, or multiple types of semiconductor packages, depending on the application. The different types of semiconductor packages are shown in FIG. 2 for purposes of illustration.

Electronic device 50 can be a stand-alone system that uses the semiconductor packages to perform one or more electrical functions. Alternatively, electronic device 50 can be a subcomponent of a larger system. For example, electronic device 50 can be part of a cellular phone, personal digital assistant (PDA), digital video camera (DVC), or other electronic communication device. Alternatively, electronic device 50 can be a graphics card, network interface card, or other signal processing card that can be inserted into a computer. The semiconductor package can include microprocessors, memories, application specific integrated circuits (ASIC), logic circuits, analog circuits, RF circuits, discrete devices, or other semiconductor die or electrical components. Miniaturization and weight reduction are essential for these products to be accepted by the market. The distance between semiconductor devices must be decreased to achieve higher density.

In FIG. 2, PCB 52 provides a general substrate for structural support and electrical interconnect of the semiconductor packages mounted on the PCB. Conductive signal traces 54 are formed over a surface or within layers of PCB 52 using evaporation, electrolytic plating, electroless plating, screen printing, or other suitable metal deposition process. Signal traces 54 provide for electrical communication between each of the semiconductor packages, mounted components, and other external system components. Traces 54 also provide power and ground connections to each of the semiconductor packages.

In some embodiments, a semiconductor device has two packaging levels. First level packaging is a technique for mechanically and electrically attaching the semiconductor die to an intermediate carrier. Second level packaging involves mechanically and electrically attaching the intermediate carrier to the PCB. In other embodiments, a semiconductor device may only have the first level packaging where the die is mechanically and electrically mounted directly to the PCB.

For the purpose of illustration, several types of first level packaging, including bond wire package 56 and flipchip 58, are shown on PCB 52. Additionally, several types of second level packaging, including ball grid array (BGA) 60, bump chip carrier (BCC) 62, dual in-line package (DIP) 64, land grid array (LGA) 66, multi-chip module (MCM) 68, quad flat non-leaded package (QFN) 70, and quad flat package 72, are shown mounted on PCB 52. Depending upon the system requirements, any combination of semiconductor packages, configured with any combination of first and second level packaging styles, as well as other electronic components, can be connected to PCB 52. In some embodiments, electronic device 50 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using cheaper components and a streamlined manufacturing process. The resulting devices are less likely to fail and less expensive to manufacture resulting in a lower cost for consumers.

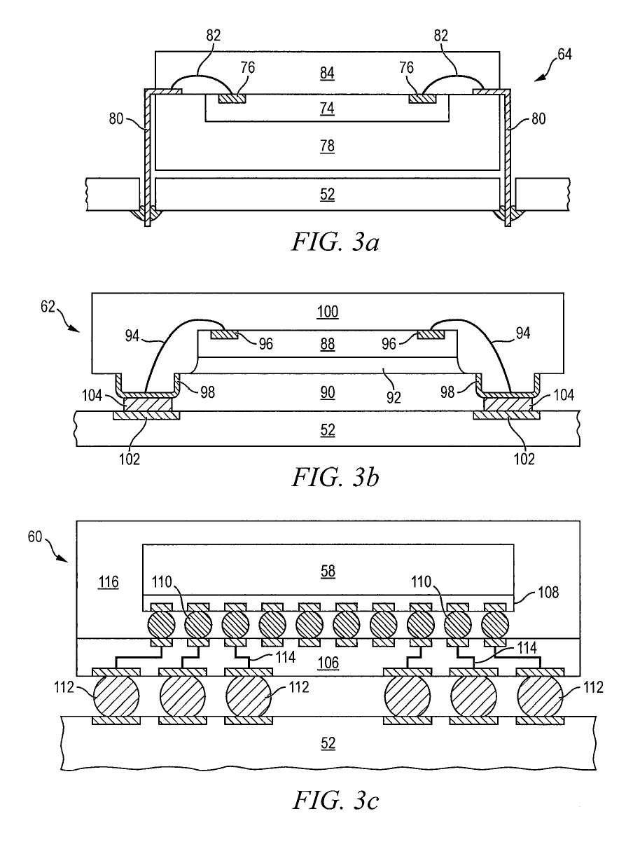

FIGS. 3a-3c show exemplary semiconductor packages. FIG. 3a illustrates further detail of DIP 64 mounted on PCB 52. Semiconductor die 74 includes an active region containing analog or digital circuits implemented as active devices, passive devices, conductive layers, and dielectric layers formed within the die and are electrically interconnected according to the electrical design of the die. For example, the circuit can include one or more transistors, diodes, inductors, capacitors, resistors, and other circuit elements formed within the active region of semiconductor die 74. Contact pads 76 are one or more layers of conductive material, such as aluminum (Al), copper (Cu), tin (Sn), nickel (Ni), gold (Au), or silver (Ag), and are electrically connected to the circuit elements formed within semiconductor die 74. During assembly of DIP 64, semiconductor die 74 is mounted to an intermediate carrier 78 using a gold-silicon eutectic layer or adhesive material such as thermal epoxy or epoxy resin. The package body includes an insulative packaging material such as polymer or ceramic. Conductor leads 80 and bond wires 82 provide electrical interconnect between semiconductor die 74 and PCB 52. Encapsulant 84 is deposited over the package for environmental protection by preventing moisture and particles from entering the package and contaminating die 74 or bond wires 82.

FIG. 3b illustrates further detail of BCC 62 mounted on PCB 52. Semiconductor die 88 is mounted over carrier 90 using an underfill or epoxy-resin adhesive material 92. Bond wires 94 provide first level packaging interconnect between contact pads 96 and 98. Molding compound or encapsulant 100 is deposited over semiconductor die 88 and bond wires 94 to provide physical support and electrical isolation for the device. Contact pads 102 are formed over a surface of PCB 52 using a suitable metal deposition process such as electrolytic plating or electroless plating to prevent oxidation. Contact pads 102 are electrically connected to one or more conductive signal traces 54 in PCB 52. Bumps 104 are formed between contact pads 98 of BCC 62 and contact pads 102 of PCB 52.

In FIG. 3c, semiconductor die 58 is mounted face down to intermediate carrier 106 with a flipchip style first level packaging. Active region 108 of semiconductor die 58 contains analog or digital circuits implemented as active devices, passive devices, conductive layers, and dielectric layers formed according to the electrical design of the die. For example, the circuit can include one or more transistors, diodes, inductors, capacitors, resistors, and other circuit elements within active region 108. Semiconductor die 58 is electrically and mechanically connected to carrier 106 through bumps 110.

BGA 60 is electrically and mechanically connected to PCB 52 with a BGA style second level packaging using bumps 112. Semiconductor die 58 is electrically connected to conductive signal traces 54 in PCB 52 through bumps 110, signal lines 114, and bumps 112. A molding compound or encapsulant 116 is deposited over semiconductor die 58 and carrier 106 to provide physical support and electrical isolation for the device. The flipchip semiconductor device provides a short electrical conduction path from the active devices on semiconductor die 58 to conduction tracks on PCB 52 in order to reduce signal propagation distance, lower capacitance, and improve overall circuit performance. In another embodiment, the semiconductor die 58 can be mechanically and electrically connected directly to PCB 52 using flipchip style first level packaging without intermediate carrier 106.

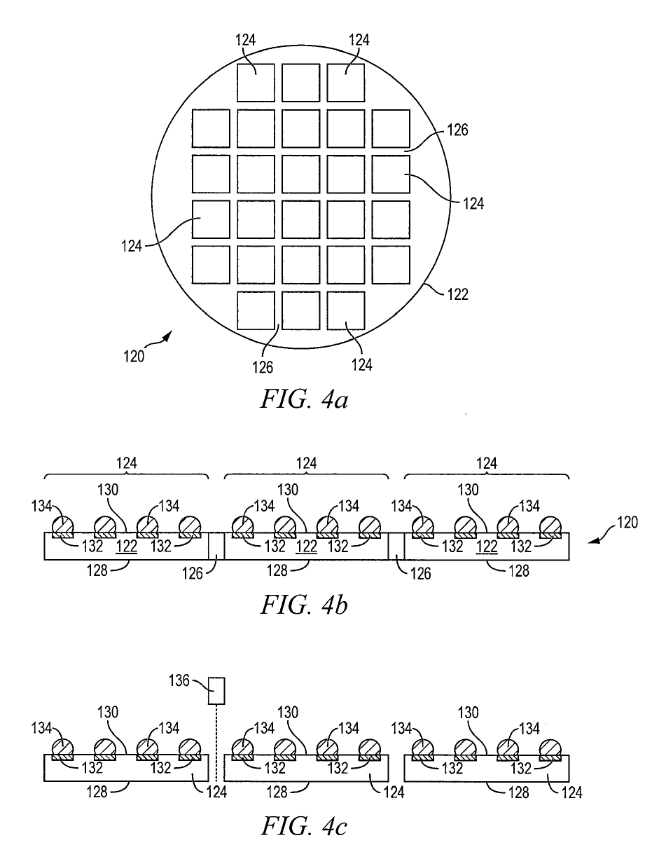

FIG. 4a shows a semiconductor wafer 120 with a base substrate material 122, such as silicon, germanium, gallium arsenide, indium phosphide, or silicon carbide, for structural support. A plurality of semiconductor die or components 124 is formed on wafer 120 separated by inter-die wafer area or saw streets 126 as described above. Saw streets 126 provide cutting areas to singulate semiconductor wafer 120 into individual semiconductor die 124.

FIG. 4b shows a cross-sectional view of a portion of semiconductor wafer 120. Each semiconductor die 124 has a back surface 128 and active surface 130 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 130 to implement analog circuits or digital circuits, such as digital signal processor (DSP), ASIC, memory, or other signal processing circuit. Semiconductor die 124 may also contain integrated passive devices (IPDs), such as inductors, capacitors, and resistors, for RF signal processing. In one embodiment, semiconductor die 124 is a flipchip type die.

An electrically conductive layer 132 is formed over active surface 130 using PVD, CVD, electrolytic plating, electroless plating process, or other suitable metal deposition process. Conductive layer 132 can be one or more layers of Al, Cu, Sn, Ni, Au, Ag, or other suitable electrically conductive material. Conductive layer 132 operates as contact pads electrically connected to the circuits on active surface 130. Contact pads 132 can be disposed side-by-side a first distance from the edge of semiconductor die 124, as shown in FIG. 4b. Alternatively, contact pads 132 can be offset in multiple rows such that a first row of contact pads is disposed a first distance from the edge of the die, and a second row of contact pads alternating with the first row is disposed a second distance from the edge of the die.

An electrically conductive bump material is deposited over conductive layer 132 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 132 using a suitable attachment or bonding process. In one embodiment, the bump material is reflowed by heating the material above its melting point to form balls or bumps 134. In some applications, bumps 134 are reflowed a second time to improve electrical contact to conductive layer 132. Bumps 134 can also be compression bonded to conductive layer 132. Bumps 134 represent one type of interconnect structure that can be formed over conductive layer 132. The interconnect structure can also use stud bump, micro bump, or other electrical interconnect.

In FIG. 4c, semiconductor wafer 120 is singulated through saw street 126 using a saw blade or laser cutting tool 136 into individual semiconductor die 124.

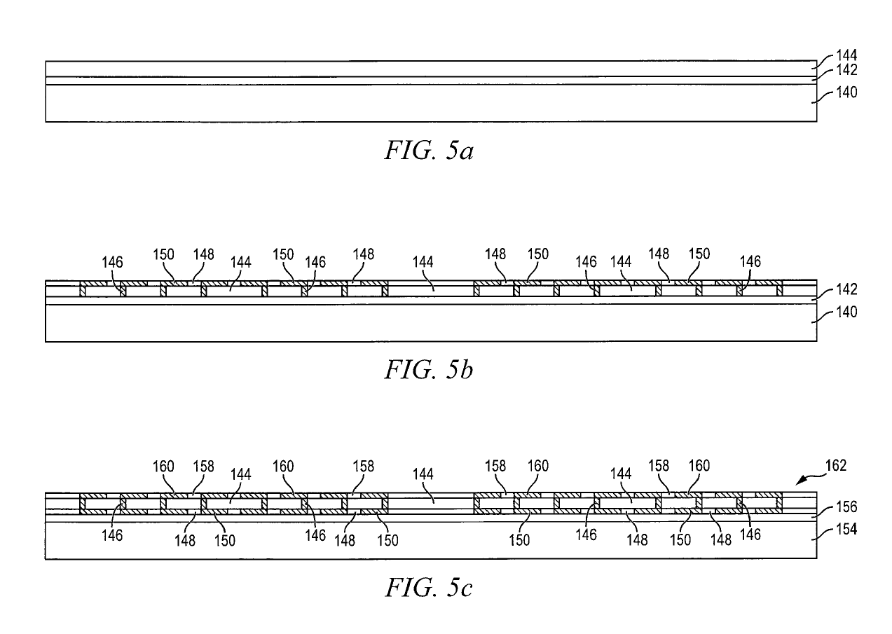

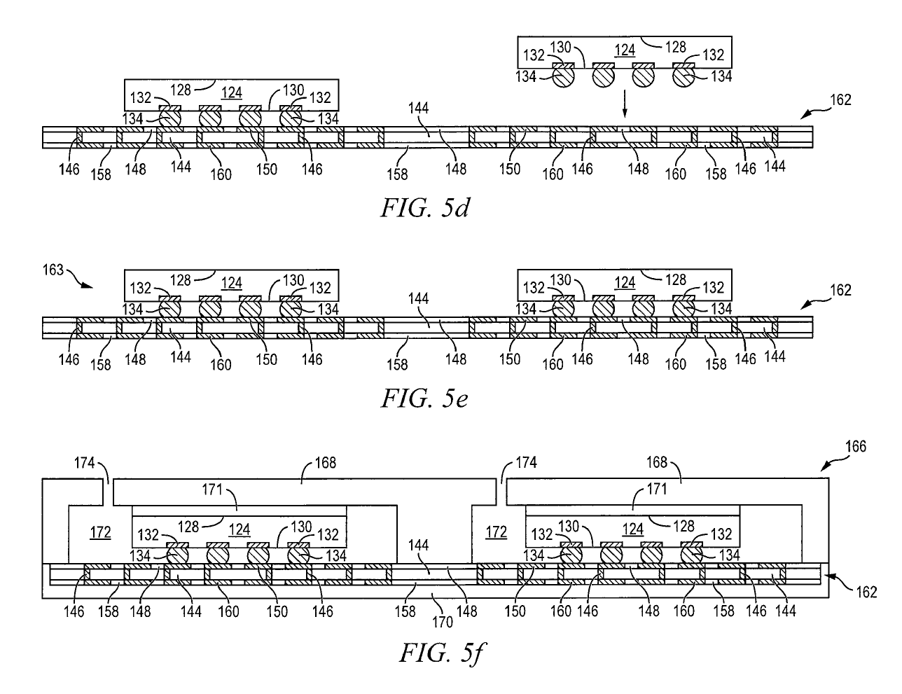

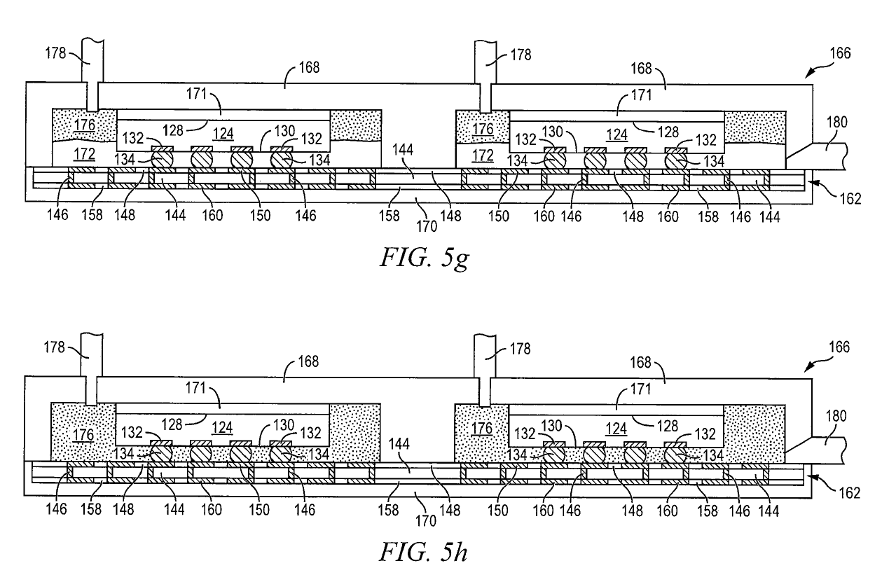

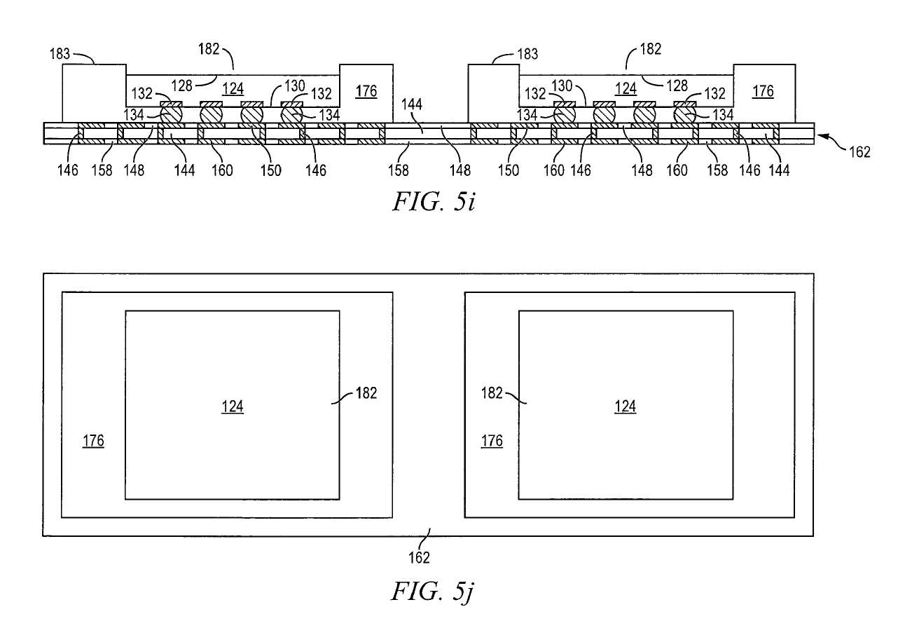

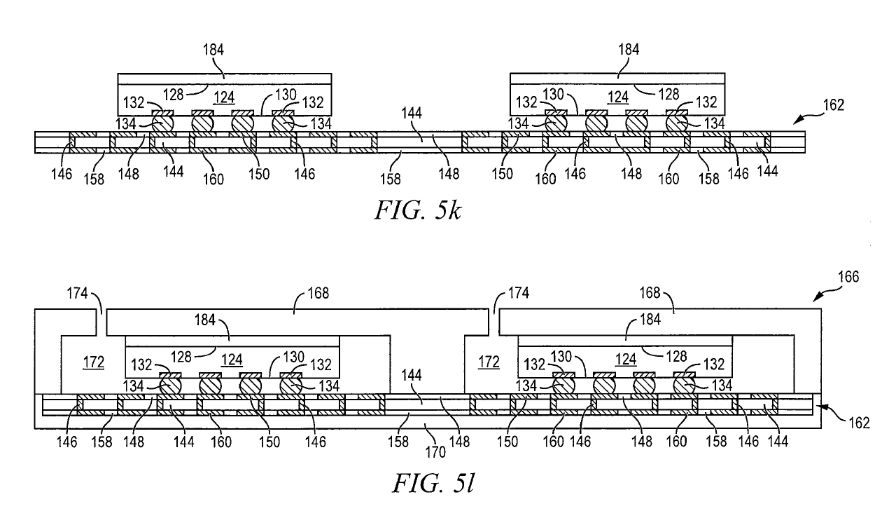

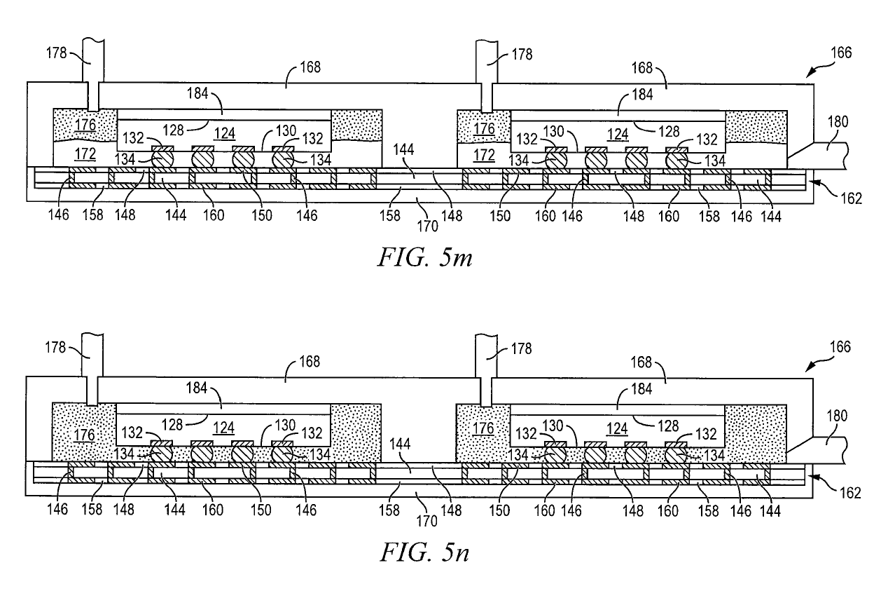

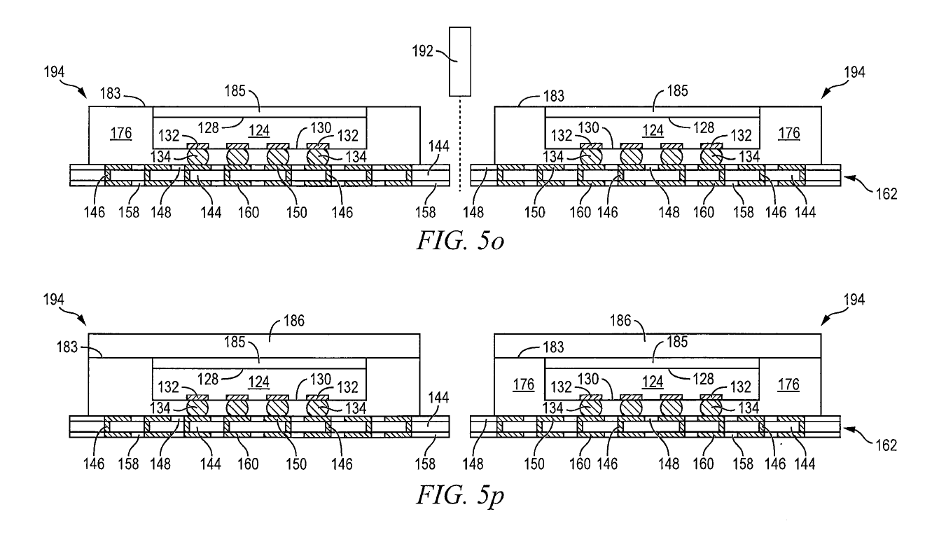

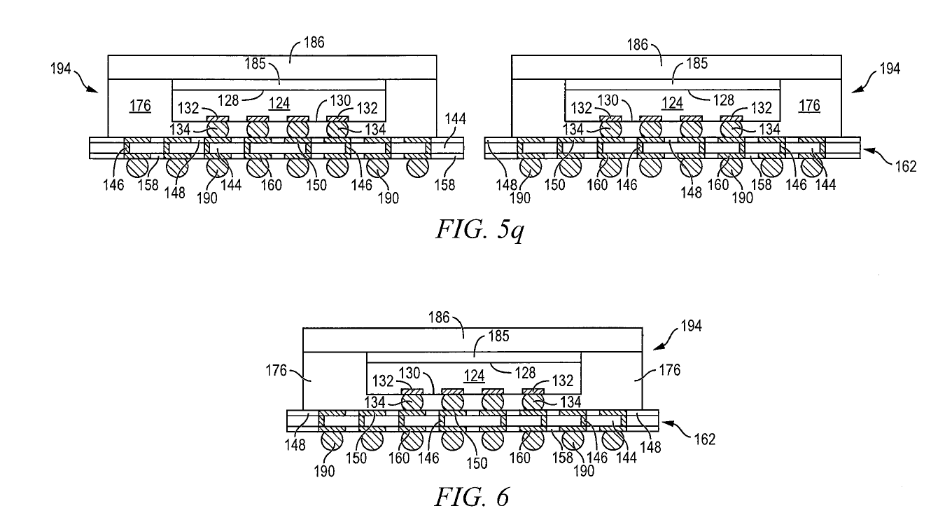

FIGS. 5a-5q illustrate, in relation to FIGS. 2 and 3a-3c, a process of forming a TIM within recesses of a MUF material. In FIG. 5a, a temporary substrate or carrier 140 contains sacrificial base material such as silicon, polymer, beryllium oxide, or other suitable low-cost, rigid material for structural support. An interface layer or double-sided tape 142 is formed over carrier 140 as a temporary adhesive bonding film or etch-stop layer. A semiconductor wafer or substrate 144 contains a base material, such as silicon, germanium, gallium arsenide, indium phosphide, or silicon carbide, for structural support. As a semiconductor wafer, substrate 144 can contain embedded semiconductor die or discrete devices. Substrate 144 can also be a multi-layer flexible laminate, ceramic, or leadframe. Substrate 144 is mounted to interface layer 142 over carrier 140.

In FIG. 5b, a plurality of vias is formed through substrate 144 using laser drilling, mechanical drilling, or deep reactive ion etching (DRIE). The vias are filled with Al, Cu, Sn, Ni, Au, Ag, titanium (Ti), tungsten (W), poly-silicon, or other suitable electrically conductive material using electrolytic plating, electroless plating process, or other suitable metal deposition process to form z-direction vertical interconnect conductive through silicon vias (TSV) 146.

An insulating or passivation layer 148 is formed over a surface of substrate 144 and conductive vias 146 using PVD, CVD, printing, spin coating, spray coating, sintering or thermal oxidation. The insulating layer 148 contains one or more layers of silicon dioxide (SiO2), silicon nitride (Si3N4), silicon oxynitride (SiON), tantalum pentoxide (Ta2O5), aluminum oxide (Al2O3), or other material having similar insulating and structural properties. A portion of insulating layer 148 is removed by an etching process to expose substrate 144 and conductive vias 146.

An electrically conductive layer or RDL 150 is formed over the exposed substrate 144 and conductive vias 146 using a patterning and metal deposition process such as printing, PVD, CVD, sputtering, electrolytic plating, and electroless plating. Conductive layer 150 can be one or more layers of Al, Cu, Sn, Ni, Au, Ag, or other suitable electrically conductive material. Conductive layer 150 is electrically connected to conductive vias 146.

In FIG. 5c, a temporary substrate or carrier 154 contains sacrificial base material such as silicon, polymer, beryllium oxide, or other suitable low-cost, rigid material for structural support. An interface layer or double-sided tape 156 is formed over carrier 154 as a temporary adhesive bonding film or etch-stop layer. Leading with insulating layer 148 and conductive layer 150, substrate 144 is mounted to interface layer 156 over carrier 154. Carrier 140 and interface layer 142 are removed by chemical etching, mechanical peeling, CMP, mechanical grinding, thermal bake, UV light, laser scanning, or wet stripping to expose a surface of substrate 144 and conductive vias 146 opposite conductive layer 150.

An insulating or passivation layer 158 is formed over substrate 144 and conductive vias 146 using PVD, CVD, printing, spin coating, spray coating, sintering or thermal oxidation. The insulating layer 158 contains one or more layers of SiO2, Si3N4, SiON, Ta2O5, Al2O3, or other material having similar insulating and structural properties. A portion of insulating layer 158 is removed by an etching process to expose substrate 144 and conductive vias 146.

An electrically conductive layer or RDL 160 is formed over the exposed substrate 144 and conductive vias 146 using a patterning and metal deposition process such as printing, PVD, CVD, sputtering, electrolytic plating, and electroless plating. Conductive layer 160 can be one or more layers of Al, Cu, Sn, Ni, Au, Ag, or other suitable electrically conductive material. Conductive layer 160 is electrically connected to conductive vias 146. In another embodiment, conductive vias 146 are formed through substrate 144 after forming conductive layers 150 and/or 160. Conductive layers 150 and 160 can be formed prior to insulating layer 148 and 158, respectively. The resulting substrate 162 provides electrical interconnect vertically and laterally across the substrate.

In FIG. 5d, semiconductor die 124 from FIGS. 4a-4c are mounted to conductive layer 150 of substrate 162 using a pick and place operation with active surface 130 oriented toward the substrate. Bumps 134 are reflowed to electrically connect conductive layer 132 of semiconductor die 124 to conductive layer 150 of substrate 162. FIG. 5e shows semiconductor die 124 mounted to substrate 162 as a reconstructed wafer 163.

In FIG. 5f, semiconductor die 124 and substrate 162 are placed in chase mold 166. Chase mold 166 has an upper mold support 168 and lower mold support 170 which are brought together to enclose semiconductor die 124 and substrate 162 with open space 172. The upper mold support 168 includes an integrated releasing film 171 to block formation of MUF material over back surface 128 of semiconductor die 124. The integrated releasing film 171 can be a polymer or rubber material with a thickness of less than 100 micrometers (μm). The upper mold support 168 further includes a plurality of openings or gates 174 for injecting MUF material into open space 172.

In FIG. 5g, MUF material 176 in a liquid state is injected through gates 174 with nozzles 178 while an optional vacuum assist 180 draws pressure from the side of upper mold support 168 and lower mold support 170 to uniformly fill open space 172 around semiconductor die 124 and substrate 162 with the MUF material. MUF material 176 can be an encapsulant, molding compound, or polymer composite material, such as epoxy resin with filler, epoxy acrylate with filler, or polymer with proper filler. FIG. 5h shows MUF material 176 disposed around and between semiconductor die 124 and substrate 162. The integrated releasing film 171 blocks formation of MUF material 176 over back surface 128 of semiconductor die 124.

In FIG. 5i, semiconductor die 124 and substrate 162 are removed from chase mold 166. Back surface 128 is exposed with recesses 182 in MUF material 176 upon removal of semiconductor die 124 and substrate 162 from chase mold 166 and integrated releasing film 171. Surface 183 of MUF material 176 resides at a higher level than back surface 128 of semiconductor die 124. FIG. 5j shows a plan view of recesses 182 in MUF material 176.

In another embodiment continuing from FIG. 5e, a releasing layer 184 is formed over back surface 128 of semiconductor die 124 using PVD, CVD, printing, spin coating, spray coating, or lamination, as shown in FIG. 5k. Releasing layer 184 contains one or more layers of SiO2, Si3N4, SiON, Ta2O5, Al2O3, benzocyclobutene (BCB), polyimide (PI), polybenzoxazoles (PBO), or other suitable material having similar structural properties. In one embodiment, releasing layer 184 is a polymer or rubber material with a thickness of less than 100 μm.

In FIG. 51, semiconductor die 124 with releasing layer 184 and substrate 162 are placed in chase mold 166. Chase mold 166 has an upper mold support 168 and lower mold support 170 which are brought together to enclose semiconductor die 124 and substrate 162 with open space 172. The upper mold support 168 includes a plurality of openings or gates 174 for injecting MUF material into open space 172.

In FIG. 5m, MUF material 176 in a liquid state is injected through gates 174 with nozzles 178 while an optional vacuum assist 180 draws pressure from the side of upper mold support 168 and lower mold support 170 to uniformly fill open space 172 around semiconductor die 124 and substrate 162 with the MUF material. MUF material 176 can be an encapsulant, molding compound, or polymer composite material, such as epoxy resin with filler, epoxy acrylate with filler, or polymer with proper filler. FIG. 5n shows MUF material 176 disposed around and between semiconductor die 124 and substrate 162. Releasing layer 184 blocks formation of MUF material 176 over back surface 128 of semiconductor die 124.

Semiconductor die 124 with releasing layer 184 and substrate 162 are removed from chase mold 166. Releasing layer 184 is removed by an etching process to expose back surface 128 of semiconductor die 128. The removal of releasing layer 184 creates recesses 182 in MUF material 176, as shown in FIGS. 5i and 5j. Surface 183 of MUF material 176 resides at a higher level than back surface 128 of semiconductor die 124.

In FIG. 5o, a TIM 185 is deposited within recesses 182 over back surface 128 of semiconductor die 124. TIM 185 is a thermal epoxy, thermal epoxy resin, or thermal conductive paste. TIM 185 is contained within recesses 182 with a design thickness for efficient thermal conduction. The top surface of TIM 185 is substantially co-planar with surface 183 of MUF material 176.

The reconstituted wafer 163 is singulated through substrate 162 with saw blade or laser cutting tool 192 into individual semiconductor packages 194.

In FIG. 5p, heat spreader or heat sink 186 is positioned over and mounted to or otherwise formed over TIM 185 and surface 183 of MUF material 176. Heat spreader 186 can be Cu, Al, or other material with high thermal conductivity. Heat spreader 186 and TIM 185 form a thermally conductive path that distributes and dissipates the heat generated by the high frequency electronic components and increases the thermal performance of semiconductor die 124. With TIM 185 contained within recesses 182, the TIM remains in place with its design thickness over back surface 128 of semiconductor die 124 for efficient thermal conduction. TIM 185 contained within recesses 182 avoids a spreading out or pump-out of the TIM during formation of heat spreader 186, as well as during power cycling and other conditions of thermal mechanical stress on the semiconductor package.

In FIG. 5q, an electrically conductive bump material is deposited over conductive layer 160 of substrate 162 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 160 using a suitable attachment or bonding process. In one embodiment, the bump material is reflowed by heating the material above its melting point to form balls or bumps 190. In some applications, bumps 190 are reflowed a second time to improve electrical contact to conductive layer 160. A UBM layer can be formed under bumps 190. Bumps 190 can also be compression bonded to conductive layer 160. Bumps 190 represent one type of interconnect structure that can be formed over conductive layer 160. The interconnect structure can also use stud bump, micro bump, or other electrical interconnect.

The reconstituted wafer 163 can be singulated through substrate 162 with a saw blade or laser cutting tool after formation of bumps 190.

FIG. 6 shows semiconductor package 194 after singulation. Semiconductor die 124 is electrically connected through bumps 134 to conductive layers 150 and 160, conductive vias 146, and bumps 190 of substrate 162. Semiconductor die 124 and substrate 162 are disposed within chase mold 166 and MUF material 176 is injected through gates 174 in upper mold support 168. The integrated releasing film 171 or releasing layer 184 blocks formation of MUF material 176 over back surface 128 of semiconductor die 124 during the MUF process. Recesses 182 are created upon removal of semiconductor die 124 and substrate 162 from chase mold 166 or removal of releasing layer 184. Surface 183 of MUF material 176 resides at a higher level than back surface 128 of semiconductor die 124. TIM 185 is formed within recesses 182 of MUF material 176 with the top surface of TIM 185 substantially co-planar with surface 183 of MUF material 176. With TIM 185 contained within recesses 182, the TIM remains in place with its design thickness over back surface 128 of semiconductor die 124 during formation of heat spreader 186, as well as during power cycling and other conditions of thermal mechanical stress on semiconductor package 194. The design thickness of TIM 185 is maintained following formation of heat spreader 186 to improve heat dissipation and reduce warpage of semiconductor package 194.

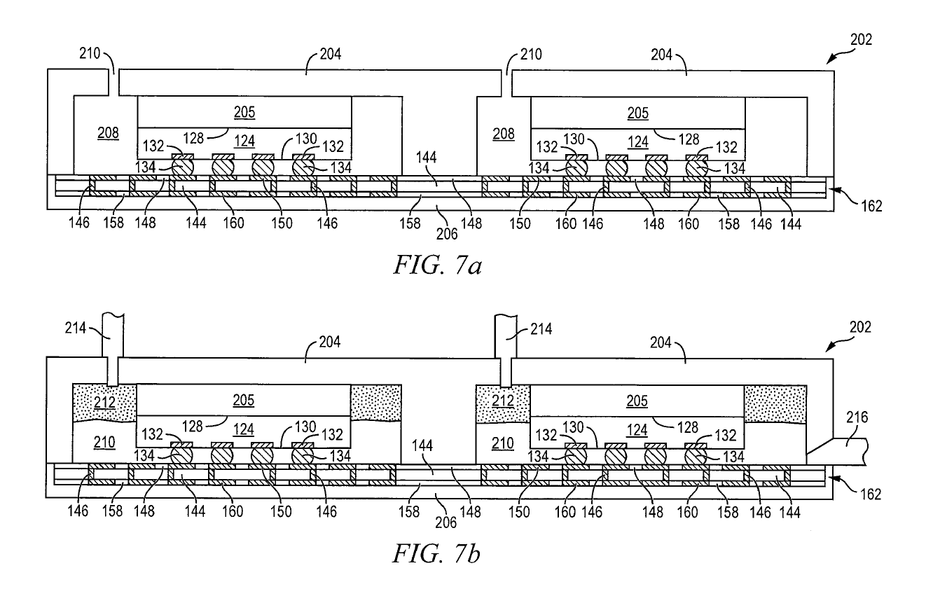

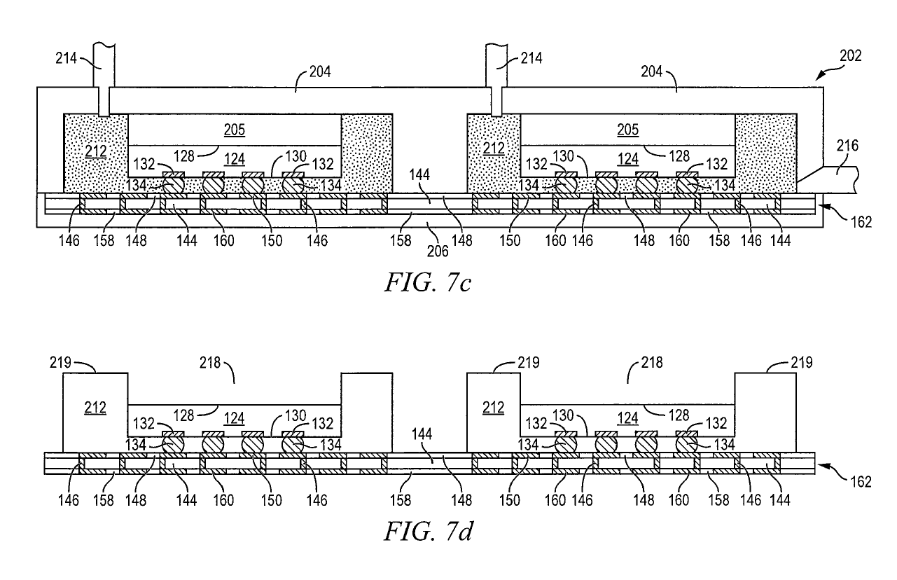

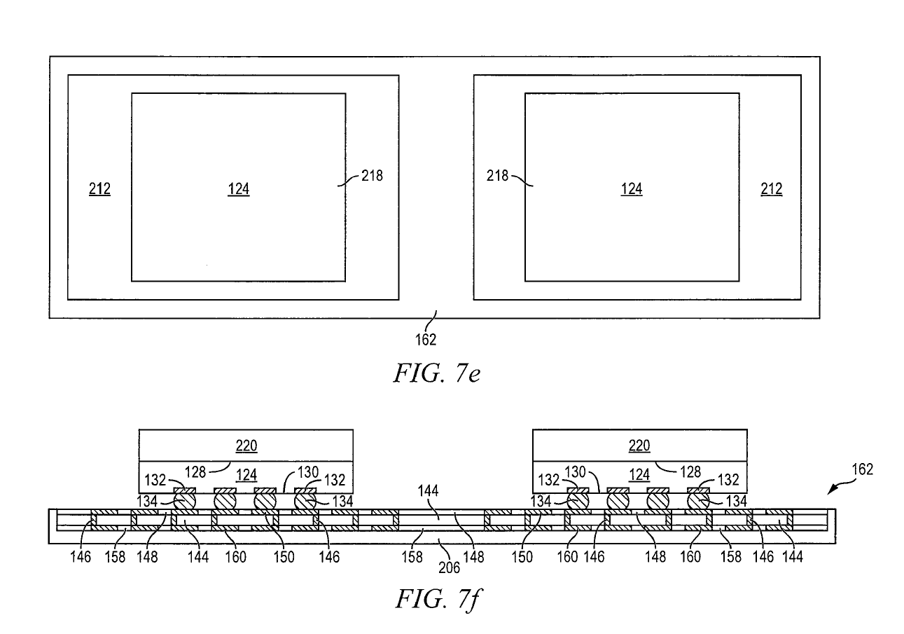

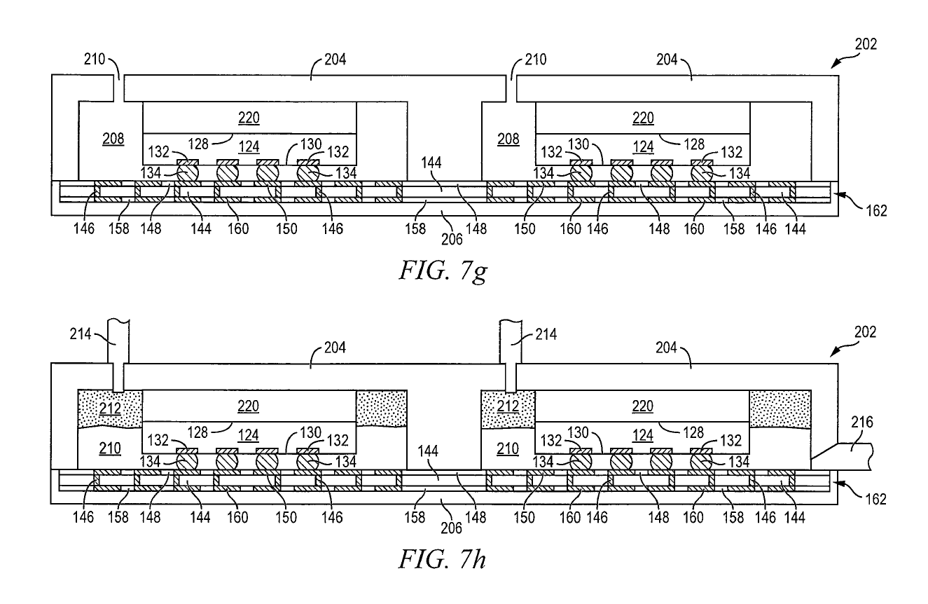

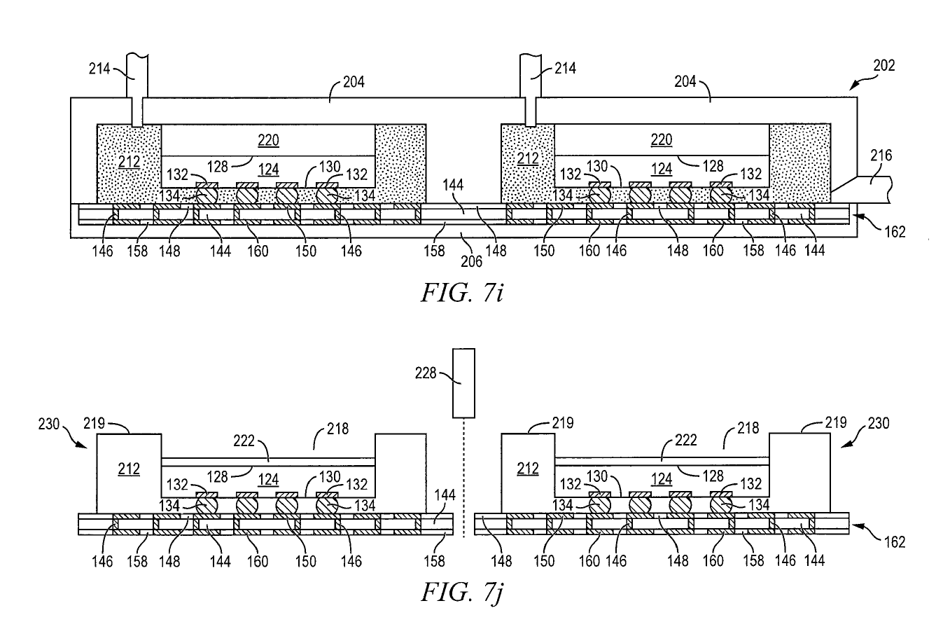

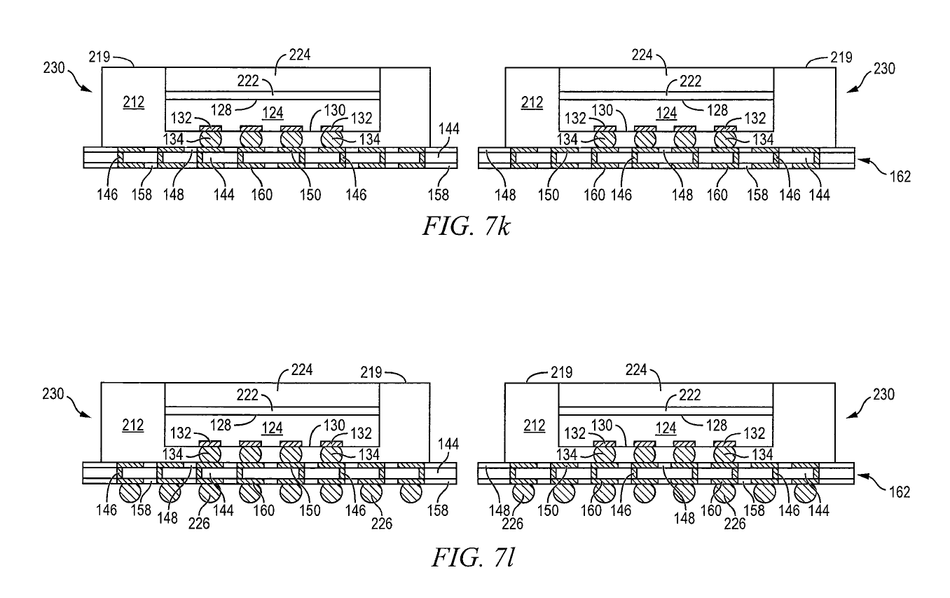

FIGS. 7a-7l illustrate, in relation to FIGS. 2 and 3a-3c, a process of forming a TIM and heat spreader within recesses of a MUF material. Continuing from FIG. 5e, semiconductor die 124 and substrate 162 are placed in chase mold 202, as shown in FIG. 7a. Chase mold 202 has an upper mold support 204 and lower mold support 206 which are brought together to enclose semiconductor die 124 and substrate 162 with open space 208. The upper mold support 204 includes integrated releasing film 205 to block formation of MUF material over back surface 128 of semiconductor die 124. The upper mold support 204 further includes a plurality of openings or gates 210 for injecting MUF material into open space 208.

In FIG. 7b, MUF material 212 in a liquid state is injected through gates 210 with nozzles 214 while an optional vacuum assist 216 draws pressure from the side of upper mold support 204 and lower mold support 206 to uniformly fill open space 210 around semiconductor die 124 and substrate 162 with the MUF material. MUF material 212 can be an encapsulant, molding compound, or polymer composite material, such as epoxy resin with filler, epoxy acrylate with filler, or polymer with proper filler. FIG. 7c shows MUF material 212 disposed around and between semiconductor die 124 and substrate 162. The integrated releasing film 205 blocks formation of MUF material 212 over back surface 128 of semiconductor die 124.

In FIG. 7d, semiconductor die 124 and substrate 162 are removed from chase mold 202. Back surface 128 is exposed with recesses 218 in MUF material 212 upon removal of semiconductor die 124 and substrate 162 from chase mold 202. Surface 219 of MUF material 212 resides at a higher level than back surface 128 of semiconductor die 124. FIG. 7e shows a plan view of recesses 218 in MUF material 212.

In another embodiment continuing from FIG. 5e, a releasing 220 is formed over back surface 128 of semiconductor die 124 using PVD, CVD, printing, spin coating, spray coating, or lamination, as shown in FIG. 7f. Releasing layer 220 contains one or more layers of SiO2, Si3N4, SiON, Ta2O5, Al2O3, BCB, PI, PBO, or other suitable material having similar structural properties. In one embodiment, releasing layer 220 is a polymer or rubber material with a thickness of 300 μm or more.

In FIG. 7g, semiconductor die 124 with releasing layer 220 and substrate 162 are placed in chase mold 202. Chase mold 202 has an upper mold support 204 and lower mold support 206 which are brought together to enclose semiconductor die 124 and substrate 162 with open space 208. The upper mold support 204 includes a plurality of openings or gates 210 for injecting MUF material into open space 208.

In FIG. 7h, MUF material 212 in a liquid state is injected through gates 210 with nozzles 214 while an optional vacuum assist 216 draws pressure from the side of upper mold support 204 and lower mold support 206 to uniformly fill open space 210 around semiconductor die 124 and substrate 162 with the MUF material. MUF material 212 can be an encapsulant, molding compound, or polymer composite material, such as epoxy resin with filler, epoxy acrylate with filler, or polymer with proper filler. FIG. 7i shows MUF material 212 disposed around and between semiconductor die 124 and substrate 162. Releasing layer 220 blocks formation of MUF material 212 over back surface 128 of semiconductor die 124.

Semiconductor die 124 with releasing layer 220 and substrate 162 are removed from chase mold 202. Releasing layer 220 is removed by an etching process to expose back surface 128 of semiconductor die 128. The removal of releasing layer 220 creates recesses 218 in MUF material 212, as shown in FIGS. 7d and 7e. Surface 219 of MUF material 212 resides at a higher level than back surface 128 of semiconductor die 124.

In FIG. 7j, a TIM 222 is deposited within recesses 218 over back surface 128 of semiconductor die 124. TIM 222 is a thermal epoxy, thermal epoxy resin, or thermal conductive paste. TIM 222 is contained within recesses 218 with a design thickness for efficient thermal conduction.

The reconstituted wafer 163 is singulated through substrate 162 with saw blade or laser cutting tool 228 into individual semiconductor packages 230.

In FIG. 7k, heat spreader or heat sink 224 is positioned over and mounted to or otherwise formed over TIM 222 within recesses 218. Heat spreader 224 can be Cu, Al, or other material with high thermal conductivity. Heat spreader 224 and TIM 222 form a thermally conductive path that distributes and dissipates the heat generated by the high frequency electronic components and increases the thermal performance of semiconductor die 124. Heat spreader 224 is contained within recesses 218 with the top surface of the heat spreader substantially co-planar with surface 219 of MUF material 212. With TIM 222 and heat spreader 224 contained within recesses 218, the TIM remains in place with its design thickness over back surface 128 of semiconductor die 124 for efficient thermal conduction. TIM 222 contained within recesses 218 avoids a spreading out or pump-out of the TIM during formation of heat spreader 224, as well as during power cycling and other conditions of thermal mechanical stress on the semiconductor package.

In FIG. 71, an electrically conductive bump material is deposited over conductive layer 160 of substrate 162 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 160 using a suitable attachment or bonding process. In one embodiment, the bump material is reflowed by heating the material above its melting point to form balls or bumps 226. In some applications, bumps 226 are reflowed a second time to improve electrical contact to conductive layer 160. A UBM layer can be formed under bumps 226. Bumps 226 can also be compression bonded to conductive layer 160. Bumps 226 represent one type of interconnect structure that can be formed over conductive layer 160. The interconnect structure can also use stud bump, micro bump, or other electrical interconnect.

Semiconductor die 124 can be singulated through substrate 162 with a saw blade or laser cutting tool after formation of bumps 226.

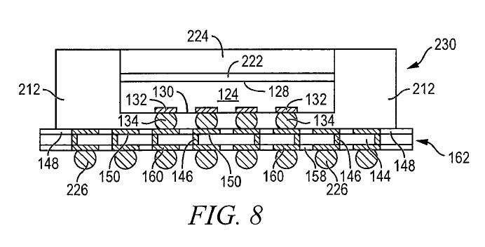

FIG. 8 shows semiconductor package 230 after singulation. Semiconductor die 124 is electrically connected through bumps 134 to conductive layers 150 and 160, conductive vias 146, and bumps 226 of substrate 162. Semiconductor die 124 and substrate 162 are disposed within chase mold 202 and MUF material 212 is injected through gates 210 in upper mold support 204. The integrated releasing film 205 or releasing layer 220 blocks formation of MUF material 212 over back surface 128 of semiconductor die 124 during the MUF process. Recesses 218 are created by removing releasing layer 220 or upon removal of semiconductor die 124 and substrate 162 from chase mold 202. Surface 219 of MUF material 212 resides at a higher level than back surface 128 of semiconductor die 124. Recesses 218 have sufficient depth to encompass TIM 222 and heat spreader 224. TIM 222 is formed within recesses 218 of MUF material 212. Heat spreader 224 is also formed recesses 218 with the top surface of the heat spreader substantially co-planar with surface 219 of MUF material 212. With TIM 222 contained within recesses 218, the TIM remains in place with its design thickness over back surface 128 of semiconductor die 124 during formation of heat spreader 224, as well as during power cycling and other conditions of thermal mechanical stress on semiconductor package 230. The design thickness of TIM 222 is maintained following formation of heat spreader 224 to improve heat dissipation and reduce warpage of semiconductor package 230.

While lone or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a substrate;
mounting a semiconductor die to the substrate;
disposing a releasing layer over the semiconductor die;
depositing a mold underfill material around the semiconductor die, releasing layer, and substrate;
forming a recess in the mold underfill material by removing the releasing layer;
forming a thermal interface material in the recess of the mold underfill material; and
forming a heat spreader over the thermal interface material.

2. The method of claim 1, further including forming a plurality of bumps over a surface of the substrate opposite the semiconductor die.

3. The method of claim 1, wherein the thermal interface material is substantially coplanar with the mold underfill material.

4. The method of claim 1, further including forming the heat spreader within the recess of the mold underfill material over the thermal interface material.

5. The method of claim 1, further including:
providing a mold chase;
disposing the semiconductor die and substrate within the mold chase; and
depositing the mold underfill material through an opening in the mold chase around the semiconductor die, releasing layer, and substrate.

6. The method of claim 5, wherein the opening in the mold chase is located in an upper mold support of the mold chase.

7. A method of making a semiconductor device, comprising:
providing a substrate;
mounting a semiconductor die to the substrate;
depositing an encapsulant around the semiconductor die and substrate while blocking formation of the encapsulant over the semiconductor die to form a recess in the encapsulant over the semiconductor die;
forming a thermal interface material in the recess of the encapsulant; and
forming a heat spreader over the thermal interface material.

8. The method of claim 7, further including:
disposing a releasing layer over the semiconductor die prior to depositing the encapsulant; and
removing the releasing layer to form the recess in the encapsulant.

9. The method of claim 7, further including:
providing a mold chase;
disposing the semiconductor die and substrate within the mold chase; and
depositing the encapsulant through an opening in the mold chase around the semiconductor die and substrate.

10. The method of claim 9, wherein the opening in the mold chase is located in an upper mold support of the mold chase.

11. The method of claim 7, further including forming an interconnect structure over a surface of the substrate opposite the semiconductor die.

12. The method of claim 7, wherein the thermal interface material is substantially coplanar with the encapsulant.

13. The method of claim 7, further including forming the heat spreader within the recess of the encapsulant over the thermal interface material.

14. A method of making a semiconductor device, comprising:
providing a substrate;
mounting a semiconductor die to the substrate;
depositing an encapsulant around the semiconductor die and substrate;
forming a recess in the encapsulant over the semiconductor die;
forming a thermal interface material in the recess of the encapsulant; and
forming a heat spreader over the thermal interface material.

15. The method of claim 14, further including:
disposing a releasing layer over the semiconductor die prior to depositing the encapsulant; and
removing the releasing layer to form the recess in the encapsulant.

16. The method of claim 14, further including:
providing a mold chase;
disposing the semiconductor die and substrate within the mold chase; and
depositing the encapsulant through an opening in the mold chase around the semiconductor die and substrate.

17. The method of claim 16, wherein the opening in the mold chase is located in an upper mold support of the mold chase.

18. The method of claim 14, further including forming an interconnect structure over a surface of the substrate opposite the semiconductor die.

19. The method of claim 14, wherein the thermal interface material is substantially coplanar with the encapsulant.

20. The method of claim 14, further including forming the heat spreader within the recess of the encapsulant over the thermal interface material.

21. A semiconductor device, comprising:
a substrate;
a semiconductor die mounted to the substrate;
an encapsulant deposited around the semiconductor die and substrate with a recess formed in the encapsulant over the semiconductor die;
a thermal interface material formed in the recess of the encapsulant; and
a heat spreader formed over the thermal interface material.

22. The semiconductor device of claim 21, further including a releasing layer disposed over the semiconductor die.

23. The semiconductor device of claim 21, further including an interconnect structure formed over a surface of the substrate opposite the semiconductor die.

24. The semiconductor device of claim 21, wherein the thermal interface material is substantially coplanar with the encapsulant.

25. The semiconductor device of claim 21, wherein the heat spreader is formed within the recess of the encapsulant over the thermal interface material.
